(19) United States
(12) Patent Application Publication
(10) Pub. No.: US 2011/0110171 A1
(43) Pub. Date: May 12, 2011

(54) POWERLESS EXTERNAL EVENT DETECTION DEVICE

(75) Inventors: David A. KAMP, Monument, CO (US); Filippo MARINELLI, Lussy-sur-Morges (CH); Thierry ROZ, Payerne (CH)

(73) Assignee: EM MICROELECTRONIC-MARIN SA, Marin (CH)

(21) Appl. No.: 12/620,365

(22) Filed: Nov. 17, 2009

(30) Foreign Application Priority Data
Nov. 12, 2009 (EP) 09175792.2

(51) Int. Cl. G11C 7/20

(52) U.S. Cl. 365/189.16

(57) ABSTRACT

The external event detection device comprises an electronic unit (22) and an external event sensor (16), the electronic unit having at least a non-volatile memory cell (24, T1) in which data relative to at least one external event detected by the external event sensor can be stored. According to the invention, the external event sensor defines an energy harvester that transforms energy from said at least one external event into electrical energy contained in an electrical stimulus pulse provided to the electronic unit. The electronic unit is arranged for storing said data by using only the electrical energy contained in the electrical stimulus pulse. In particular, the non-volatile memory cell is directly set to its written logical state from its initial logical state by the electrical stimulus pulse provided by said energy harvester. In a preferred embodiment, the electronic unit further comprises a set circuit (26) comprising a second FET transistor (T2) arranged between the ground of the electronic unit and the drain of a first FET transistor (T1) defining the non-volatile memory cell, this switch having a control gate connected to the control gate of the first FET transistor. The second FET transistor is turned on when an electrical stimulus pulse is provided to the electronic unit, connecting the drain (DRN) of the first FET transistor (T1) to ground and thus allowing the secure setting of the non-volatile memory cell.

### FIELD OF THE INVENTION

The present invention concerns a powerless external event detection device. In particular, the present invention concerns a tamper event detection device for detecting a tamper event in a protected zone or in a closed case or container. By ‘powerless detection device’ it is understood that there is no internal or external power source supplying the device for allowing this device to detect an external event. However, such a powerless detection device can be supplied with power for other functions in defined time periods, e.g. for reading the state of a memory or for resetting such a device.

The invention thus specifically deals with the reduction of the power consumption of such external event detection devices and furthermore with the increase in their security level.

### BACKGROUND OF THE INVENTION

The detection of an attempt to recover secrets from/within a protected zone, closed case, or container through the use of an electronic circuit is often implemented by mechanical means external and adjacent to the electronic circuit which permanently records the attempt by changing a physical structure of or related to this electronic circuit in a way not easily noticed by the perpetrator. This physical change can then be established by the fact that the electronic circuit is no longer functional or by measuring an electrical parameter of the electronic circuit that has been modified directly or indirectly by the mechanical means.

Another method for the detection of an external event consists of the integration of electrical detection means internal to the electronic circuit, powering this electronic circuit and waiting for the event to occur while powered. For example, the detection means can be a sensor that is configured to provide a detection signal when the sensor and the electronic circuit are powered, the occurrence of this signal being stored in a memory via a write control circuit which is also powered by a power source. Thus, the supply of power for the event detection device needs to be a battery or another power source supplying continuous power. Without such a power source or if the power source is OFF or if the energy stored in the battery becomes too low, this device will not be functional, i.e., it will be incapable of detecting and recording an event. It is indeed possible to limit the current consumption of such a detection device by implementing a ‘sleep mode’. However the detection device will be functional only when supplied. Furthermore, in the case of an internal power source like a battery, such a device will have a limited lifetime or the internal power source will have to be changed after a certain time period. This causes a security problem first because there is a risk that the detection device becomes no longer functional when an interruption of the power supply occurs, and secondly because a perpetrator could cause an interruption of the power source, stopping the electrical supply of the detection device during the time period of the attempt.

### SUMMARY OF THE INVENTION

A principal aim of the invention is to provide an electronic circuit that can detect an external event, in particular a tamper event, even if the circuit is not supplied, i.e. without any power source maintaining the electronic circuit active or in a sleep state while awaiting the occurrence of an external event.

Thus, the invention concerns an external event detection device comprising an electronic unit and an external event sensor, the electronic unit having a memory part in which data relative to at least an external event detected by the external event sensor can be stored. This device is characterized in that the external event sensor defines an energy harvester that transforms energy from said at least an external event into electrical energy contained in an electrical stimulus pulse provided to the electronic unit, and in that this electronic unit is arranged for storing said data by using only the electrical energy contained in the electrical stimulus pulse.

In other words, the invention provides a means to detect an external event and record the fact that it occurred (set a flag). It also provides means to accomplish the detection without a power source supplying the detection circuit. This is made by using the power of the external event itself applied to an energy harvester incorporated in the detection device.

It is to be noted that, in a specific embodiment of the invention, the sensor (or a part of this sensor, e.g. its circuitry) and the electronic unit can be integrated or incorporated in a unique electronic circuit.

In a preferred embodiment, the memory part comprises at least a non-volatile memory cell or element. In a first variant, this memory cell or element can not be reset. In this case, the non-volatile storage cell or element can be for example, One-Time-Programmable (OTP), “E-fuse”, anti-fuse, this list being non-exhaustive. In a second variant, the memory cell can be reset. In this other case, the non-volatile storage cell or element can be Flash, EEPROM, EPROM, MRAM, RRAM, PCM, this list being non-exhaustive.

In a preferred variant, the non-volatile memory cell is formed by a first FET transistor having a control gate, a source region and a drain region, the control gate being connected to a stimulus input of the electronic unit which directly receives an electrical stimulus pulse of the energy harvester when a specific external event occurs.

In another preferred embodiment, the detection device is characterized in that the electronic unit further comprises reset means for resetting the non-volatile memory cell in which data relative to at least an external event detected by the external event sensor can be stored.

A main feature of the invention is to have an energy harvester that transforms the external event to be detected into electrical energy used to supply the electronic means arranged for storing the fact that such an external event occurs. Here is a non-exhaustive list of the possible external events and related harvesters:
Electrical event: Electrostatic discharge;
Mechanical event: Piezoelectric element, dynamo;
Light event: Photodiode(s), solar cell(s);
Chemical event: Battery (detection of the mixing of ions);
Heat event: Thermopile;
Electromagnetic event: Antenna, rectifier, solenoid;
Pressure event: Barometer unit.

### BRIEF DESCRIPTION OF THE DRAWINGS

Other features and advantages of the present invention will appear more clearly from the following detailed description of illustrative embodiments of the detection device according to the invention, given purely by way of non-limiting examples, in conjunction with the drawings in which:

FIG. 1 shows the general concept of the invention applied to a lock;

FIG. 2 shows the basic architecture of a first embodiment of the external event detection device according to the invention;

FIG. 3 shows a preferred electronic design of the first embodiment;

FIG. 4 shows a second embodiment of the external event detection device according to the invention;

FIG. 5 shows the basic architecture of a third embodiment of the external event detection device according to the invention;

FIG. 6 shows a preferred electronic design of the third embodiment;

FIG. 7 shows the architecture of a fourth embodiment of the external event detection device according to the invention.

### DETAILED DESCRIPTION OF EMBODIMENTS OF THE INVENTION

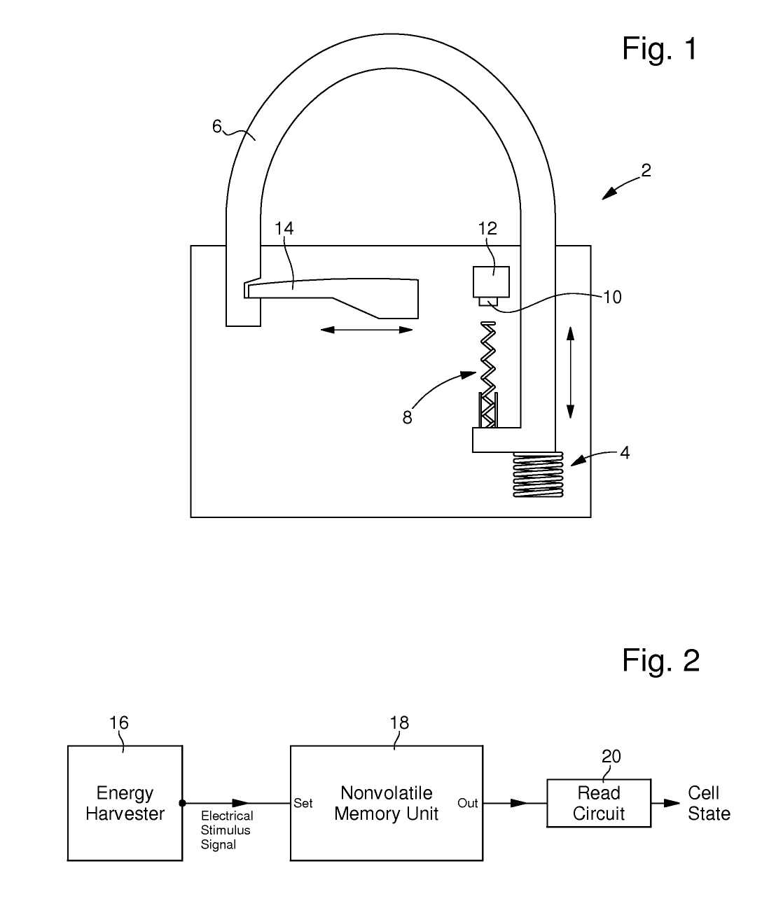

FIG. 1 shows schematically a lock 2, represented in its closed state, equipped with an external event detection device which has an external event sensor 10 and an electronic unit 12 according to the present invention. In this application, the sensor is formed by a piezoelectric element and associated circuitry arranged for providing an electrical power signal to the electronic unit when a certain pressure is applied on the piezoelectric element. This electrical power signal will be named ‘electrical stimulus signal’ in the present description of the invention. In other words, the sensor 10 defines an energy harvester according to the present invention. This sensor transforms energy from an external event applied on it into electrical energy contained in an electrical stimulus pulse that forms an electrical stimulus signal provided to the electronic unit.

The aim of this detection device is to detect if a tamper event has occurred in a zone or in a case or container protected by this lock. If the lock is forced, i.e. tampered with, the spring 4 will push up the piece 6 and the spring 8 will apply a force on the piezoelectric element. This external event is stored in a memory part of the detection device. Before opening the lock, an authorized user will have to first read the memory to know if a tamper event has occurred.

FIG. 2 shows the basic architecture of a first embodiment of the external event detection device according to the invention. The DC electrical energy of an external event is collected by the sensor forming an energy harvester 16 and provided to a memory part of the electronic unit, in the variant of FIG. 2 formed by a Non-Volatile Memory (NVM) unit 18, comprising at least one NVM cell, through an electrical stimulus signal line. In the case of the lock of FIG. 1, this energy is provided by the force applied by the spring 8 on the piezoelectric element of the sensor 10. The memory part 18 is arranged for storing data relative to at least one external event detected by the external event sensor 16. According to the invention, the electronic unit is arranged for storing said data by using only the electrical energy contained in the electrical stimulus pulse generated by the external event acting on the sensor. Thus, the detection device of FIG. 2 defines a powerless detection device. This is also the case for all other embodiments of the invention that will be further described.

The electrical energy that the energy harvester (piezoelectric element and associated circuitry in the case of FIG. 1) has to give is the energy needed to raise the voltage on the input capacitance of the electronic unit corresponding to the switching voltage plus the energy needed to switch the NVM cell and lost energy, i.e.:
Energy needed to raise the voltage on the input capacitance:

$${E}_{r} = \frac{1}{2} {C}_{input} {V}_{sw}^{2}$$

where Cᵢₙₚᵤₜ is the input capacitance
V_{SW} is the switching voltage
Typically, for an EEPROM technology:

$${E}_{r} = \frac{1}{2} ( 20 pF ) {( 16 V )}^{2} = 2.6 nJ$$

Energy needed to switch the cell:
   E_{S}=I_{SW}T_{SW}V_{SW}
      where I_{SW} is the switching current
      T_{SW} is the switching time
Typically, for an EEPROM technology:
   E_{S}=(100nA)(5 ms)(16V)=8nJ
      So the total electrical energy needed is typically of the order of 10 nJ.

For example, the piezoelectric element “PIC 151” (ceramic PZT), sold by the German company Physik Instrumente (PI), can be used to produce the needed energy and voltage to set a flag in the NVM cell. With an Input capacitance of 20 pF, 10 nJ can be generated by such a piezoelectric element having a capacity C_{PZT} of approximately 19 pF, with a voltage value of approximately 16 V across this Input capacitance, by applying a force of about 1.25 N on the piezoelectric element. It is possible to generate more than 10 nJ, for instance 20 nJ with such a piezoelectric element by increasing the applied force. If needed, a force amplifier can be arranged between the piezoelectric element and the spring (i.e. the element generating an external force used by the energy harvester when an external event occurs). In case the piezoelectric element would generate a voltage significantly greater than the needed switching voltage for the memory cell, a protection element or circuit can be added between the piezoelectric element and the electronic unit or in an input part of such an electronic unit.

The electronic unit further comprises a readout circuit 20 allowing, when powered, the reading of the logical state of the NVM cell 18. The read circuit is only used during the reading phase (so only when the circuit is supplied). The read circuit is designed so that it will not interfere with the setting of the memory cell (whether the power supply is present or not). When the device is supplied, the read circuit will enable a read of the non-volatile memory cell and the output of the read circuit will return, e.g., a logical ‘0’ if no tamper event occurred and a logical ‘1’ if a tamper event has occurred. Since this circuit is not resettable, it can detect only one tamper event.

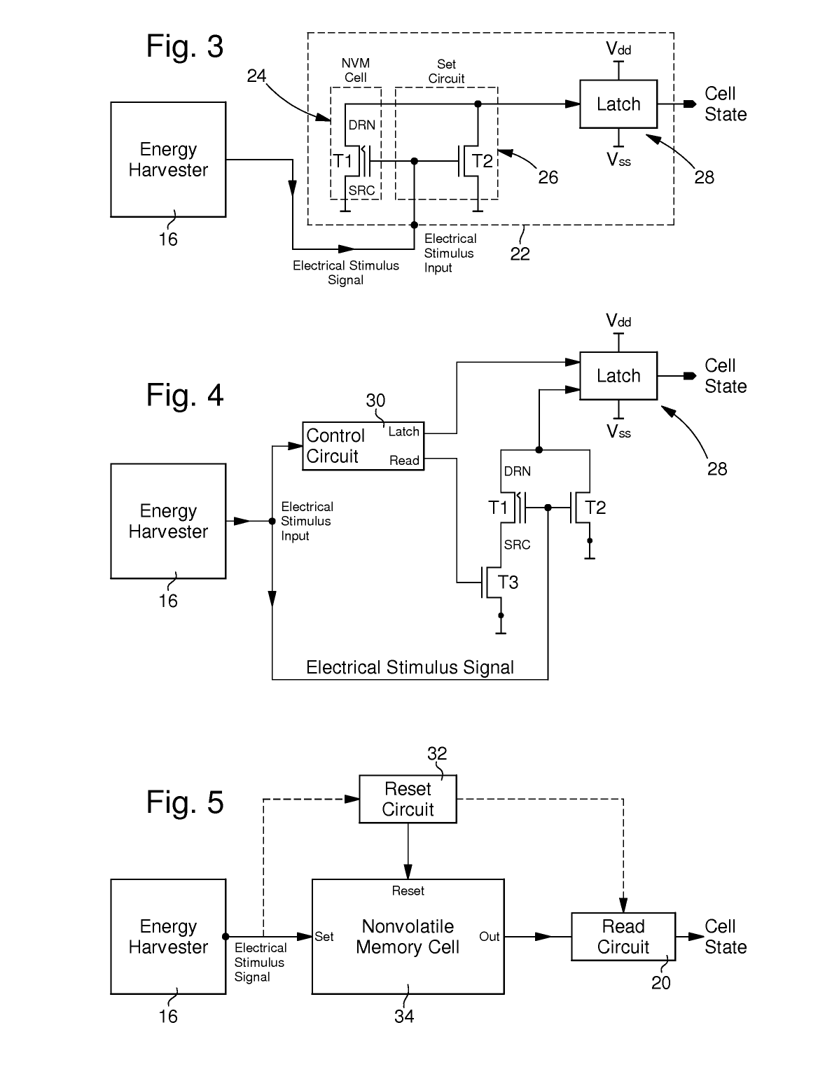

FIG. 3 shows a preferred electronic design of the previously described first embodiment. The non-volatile memory cell 24 is directly set to its written logical state from its initial logical state by an electrical stimulus pulse provided by the energy harvester 16. The NVM cell 24 is formed by a first FET transistor T1 having a control gate, a source region SRC and a drain region DRN. The control gate is connected to a stimulus input of the electronic unit 22 receiving the electrical stimulus pulse/signal of said energy harvester.

The electronic unit 22 further comprises a set circuit 26 defining a switch arranged between the ground of the electronic unit and the drain DRN of the first FET transistor. This switch is formed by a second FET transistor T2 having a control gate connected to the electrical stimulus input and is turned on when an electrical stimulus pulse is provided to the electronic unit, connecting the drain of the first FET transistor to ground (0 V) and thus allowing the secure setting of the non-volatile memory cell 24 to the logical ‘1’ state.

The electronic unit 22 comprises reading means of said non-volatile memory cell which is active only when supplied by a power source. This reading means is formed by a latch 28 having its input connected to the drain DRN of said first FET transistor and automatically providing at its output, when a power supply is applied by an external device/reader, a signal indicating the state of the NVM cell.

FIG. 4 shows a second embodiment of the external event detection device according to the invention. This second embodiment also concerns a variant without reset and further comprises in the electronic unit a control circuit 30 and a third FET transistor T3 controlled by this control circuit and arranged between the ground of the electronic unit and the source of the first FET transistor. The control circuit also controls the latch so as to disconnect this latch from the drain of the memory transistor T1 when an electrical stimulus pulse is provided to the electrical stimulus input.

The operation of this implementation can be summarized as follows:

A) Following fabrication, the memory transistor T1 is in the non-tampered state (e.g. conductive state);

B) Power is applied and thus the transistor T3 is turned ON, the non-tampered state being so written into the Latch 28, which drives its output to the logic low voltage level (this step is provided in a preferred implementation to secure the initial state of the Latch);

C) The circuit is deployed without power supply (no electrical power source);

D) A tamper event occurs supplying an electrical stimulus pulse to the electrical Stimulus Input of the electronic unit. The transistor T2 turns ON thus grounding the drain DRN of the transistor T1 and the transistor T3 is turned OFF because there is no power for control circuit 30 to drive the gate of T3. The transistor T1 is thus set to its tampered state (non-conductive state) by the power of the stimulus pulse itself;

E) Power is again supplied to the circuit. The transistor T3 is turned on, and the set state is written into the Latch, which drives its output to the logical ‘1’, or high voltage, level (external event detected).

FIG. 5 shows the basic architecture of a third embodiment of the external event detection device according to the invention. In this third embodiment, the electronic unit comprises reset means for resetting the non-volatile memory cell.

The electrical energy of the external event is collected at the electrical stimulus input of the electronic unit and, as in the previous embodiments, a corresponding data is written in the NVM cell 34. This NVM cell has a reset input receiving a reset signal from a reset circuit 32. This reset circuit needs to be power supplied for resetting the memory cell. In a variant, the reset circuit has an input receiving the stimulus input signal.

When power is supplied is present, the reset circuit allows resetting the non-volatile memory cell after an external event has been detected and this cell set. This allows reuse of the external event detector after one detected external event. Let us consider the case of a security device in which the detection device according to this embodiment has been tampered with. When the detection device is supplied following a tamper event, the read circuit will enable a read of the non-volatile memory cell and the read output will be a logical ‘1’. Once this tamper event has been acknowledged, the user can reset the non-volatile memory cell through the reset circuit 32.

The reset circuit and the read circuit are only used when the detection device is supplied with power. These elements are designed so that they will not interfere with the setting of the memory cell during a tamper event (whether the supply is present or not).

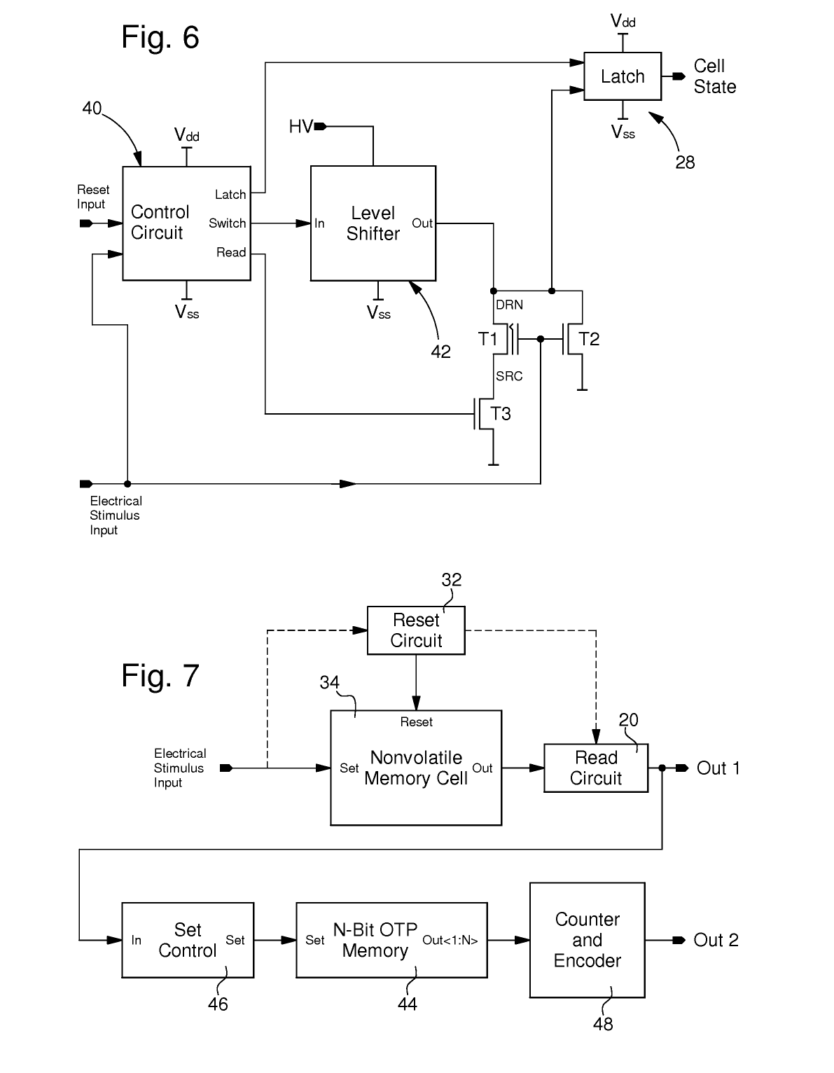

FIG. 6 shows a preferred electronic design of the third embodiment. The reset circuit is formed by a control circuit 40 and a level shifter 42 receiving a High Voltage (HV). The level shifter is controlled by the control circuit 40. In a variant, the level shifter can be formed by a high voltage inverter (CMOS Inverter). When the detection device is supplied, the latch 28 will automatically have a logical state corresponding to the logical state of the memory transistor T1. If this transistor T1 is set, the user takes note that a given external event has been detected. Then, the user can reset the memory cell so as to reuse the detection device. When a reset signal is received at the reset input of the control circuit 40, then the outputs of this control circuit are switched as follows:

The latch output is driven to 0 V instructing the latch to turn OFF for protecting itself from the high voltage which will be applied to the drain DRN of transistor T1.

The read output is driven to 0 V, turning OFF transistor T3 and thus disconnecting the source SRC of transistor T1 from ground.

The switch output is driven high to the power supply level and thus the level shifter 42 provides at its output a High Voltage signal for erasing the memory cell which returns to its non-tampered state.

After the reset step has been terminated, the level shifter output is turned OFF (high impedance so that it is not driven), the latch output is driven high and the read output is driven high again. Thus, the latch will then also be reset by the voltage level of the drain of memory cell T1. Then, the power supply can be removed and the detection device is again reusable as a powerless detection device.

FIG. 7 shows the architecture of a fourth embodiment of the external event detection device according to the invention. This FIG. 7 is a block diagram of a resettable external event detector with a multi-Bit One-Time-Programmable (OTP) back-up storage. The aim of this improvement is to have a higher security level. A perpetrator or hacker could be able to reset the detection device according to the third embodiment previously described with sophisticated electronic means. In such a case, the tamper event will no longer be stored in the detection device. To overcome such a possible situation, the fourth embodiment is characterized in that the electronic unit further comprises a One-Time-Programmable memory (OTP Memory), a bit of which is automatically written when this electronic unit is powered and the non-volatile memory cell is in the written/tampered state.

In the variant represented in FIG. 7, the OTP memory 44 comprises several Bits (N Bits). When the detection device is supplied with power, the read circuit 20 provides at its output the logical state of the NVM cell 34. The set control circuit 46 determines if this logical state corresponds to a set state. If this is the case, the set control circuit will set a Bit of the N-Bit OTP memory 44 which is not already set. Preferably, the Bits of the OTP memory are successively set each time the non-volatile memory cell is set after a reset action, until all Bits of this OTP memory are set. A Counter and Encoder circuit 48 counts the number of set Bits in the OTP memory and provides the result in a coded format.

The operation of the detection device of FIG. 7 can be summarized as follows:

A) Power is supplied to the detection device. The NVM Cell is reset to its reset state (e.g. conductive state), and this reset state is indicated at Out 1 (e.g. as a logic low voltage level);

B) The number of set Bits in the OTP memory is read at Out 2 (if not already done before). This number has to be stored in an external device for comparison with a further result obtained the next time the detection device is checked;

C) The circuit is deployed without power supplied;

D) A tamper event occurs generating an electrical stimulus pulse provided at the electrical stimulus input;

E) The NVM Cell is set to its tampered state;

F) Power is supplied to the circuit;

G) The set state is read at output Out1 (e.g., as a logical ‘1’ or high voltage level);

H) The set control circuit drives the Set input of the N-Bit OTP Memory for programming the first or next Bit of its N Bits to the set state;

I) This set state is then read by the counter and encoder circuit, which outputs an encoded group of bits representing how many bits within the N-Bit memory are set.

Steps A) through I) can be repeated up to an additional N-1 times.

In a variant, the OTP memory is set at the same time that the NVM memory is set by a detected external event. This variant however requires more energy in the electrical stimulus pulse. Thus, to automatically write the OTP memory only when the electronic unit is supplied is advantageous for the powerless detection device of the present invention.

What is claimed is:

1. An external event detection device comprising an electronic unit and an external event sensor, the electronic unit having a memory part in which data relative to at least one external event detected by said external event sensor can be stored, wherein said external event sensor defines an energy harvester that transforms energy from said at least one external event into electrical energy contained in an electrical stimulus pulse provided to said electronic unit, and in that this electronic unit is arranged for storing said data by substantially using only said electrical energy contained in said electrical stimulus pulse.

2. The external event detection device according to claim 1, wherein said memory part comprises at least a non-volatile memory cell.

3. The external event detection device according to claim 2, wherein said non-volatile memory cell is directly set to its written logical state from its initial logical state by said electrical stimulus pulse provided by said energy harvester.

4. The external event detection device according to claim 3, wherein said non-volatile memory cell is formed by a first FET transistor having a control gate, a source region and a drain region, the control gate being connected to a stimulus input of said electronic unit receiving said electrical stimulus pulse of said energy harvester.

5. The external event detection device according to claim 4, wherein said electronic unit further comprises a set circuit formed by a switch arranged between the ground of the electronic unit and the drain of the first FET transistor, this switch having a control gate connected to said stimulus input and being turned on, when an electrical stimulus pulse is provided to the electronic unit thereby connecting the drain of the first FET transistor to ground, thus allowing the secure setting of the non-volatile memory cell.

6. The external event detection device according to claim 5, wherein said switch is formed by a second FET transistor.

7. The external event detection device according to claim 4, wherein said electronic unit comprises reading means of said non-volatile memory cell which are active when powered by a power source.

8. The external event detection device according to claim 7, wherein said reading means comprises a latch having its input connected to the drain of said first FET transistor and providing at its output a signal relative to the state of this first FET transistor.

9. The external event detection device according to claim 7, wherein said electronic unit further comprises a control circuit (30) and a third FET transistor controlled by this control circuit and arranged between the ground of the electronic unit and the source of the first FET transistor.

10. The external event detection device according to claim 2, wherein said electronic unit comprises reset means for resetting said non-volatile memory cell.

11. The external event detection device according to claim 4, wherein said electronic unit comprises reset means for resetting said non-volatile memory cell.

12. The external event detection device according to claim 11, wherein said reset means comprises a control circuit and a level shifter controlled by this control circuit.

13. The external event detection device according to claim 10, wherein the electronic unit further comprises an OTP memory a bit of which is automatically set when this electronic unit is powered and said non-volatile memory cell has been set to its written state.

14. The external event detection device according to claim 13, wherein said OTP memory comprises several Bits which are successively set each time the non-volatile memory cell is set after a reset action.
